(19) United States
(12) Patent Application Publication
(10) Pub. No.: US 2024/0429230 A1
(43) Pub. Date: Dec. 26, 2024

(54) INTEGRATED RESISTORS WITH INCREASED SHEET RESISTANCE FOR RF APPLICATIONS AND METHODS OF FABRICATING THE SAME

(71) Applicant: Wolfspeed, Inc., Durham, NC (US)

(72) Inventors: Matthew King, Wake Forest, NC (US); Chris Hardiman, Cary, NC (US); Kyle Bothe, Cary, NC (US); Jeremy Fisher, Raleigh, NC (US)

(21) Appl. No.: 18/337,657

(22) Filed: Jun. 20, 2023

(51) Int. Cl. H01L 27/06; H01L 21/8252; H01L 23/66; H01L 29/20; H01L 29/66; H01L 29/778

(52) U.S. Cl. CPC H01L 27/0629; H01L 21/8252; H01L 23/66; H01L 29/2003; H01L 29/66462; H01L 29/7787; H01L 2223/6683

(57) ABSTRACT

A semiconductor device includes a semiconductor structure comprising first and second semiconductor layers having different bandgaps, first and second contacts on the semiconductor structure and free of a gate structure therebetween, and a resistor comprising a portion of the semiconductor structure that electrically connects the first and second contacts. The portion of the semiconductor structure may be a second portion of the second semiconductor layer that is recessed in thickness relative to a first portion thereof, and/or may include a passivation layer in direct contact with the second semiconductor layer. Related devices, packages, and fabrication methods are discussed.

### FIELD

The inventive concepts described herein relate to semiconductor devices, and more particularly, to semiconductor-based resistors and related fabrication methods.

### BACKGROUND

Power semiconductor devices are widely used to carry large currents, support high voltages and/or operate at high frequencies such as radio frequencies. A wide variety of power semiconductor devices are known in the art including, for example, power switching devices and power amplifiers. Many power semiconductor devices are implemented using various types of field effect transistor (FET) devices including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally-diffused metal-oxide semiconductor) transistors, etc.

Modern power semiconductor devices are generally fabricated from wide bandgap semiconductor materials (i.e., having a band-gap greater than 1.40 eV). For example, power HEMTs may be fabricated from gallium nitride (GaN) or other Group III nitride based material systems that are formed on a silicon carbide (SiC) substrate. As used herein, the term “Group III nitride” refers to those semiconducting compounds formed between nitrogen and the elements in Group III of the periodic table, usually aluminum (Al), gallium (Ga), and/or indium (In). These compounds have empirical formulas in which one mole of nitrogen is combined with a total of one mole of the Group III elements. For high power, high temperature, and/or high frequency applications, devices formed in wide bandgap semiconductor materials such as silicon carbide (2.996 eV bandgap for alpha silicon carbide at room temperature) and the Group III nitrides (e.g., 3.36 eV bandgap for gallium nitride at room temperature) may provide higher electric field breakdown strengths and higher electron saturation velocities as compared to gallium arsenide (GaAs) and silicon (Si) based devices.

In order to increase the output power and current handling capabilities, power semiconductor devices may be implemented in a “unit cell” configuration in which a large number of individual unit cell transistor structures of the active region are electrically connected (e.g., in parallel) to function as a single power semiconductor device. In high power applications, such a power semiconductor device may include thousands or tens of thousands of unit cells implemented in a single chip or “die.” A die or chip may include a small block of semiconducting material or other substrate in which electronic circuit elements are fabricated.

Field effect transistors such as HEMTs and MOSFETs may be classified into depletion mode and enhancement mode types, corresponding to whether the transistor is in an ON-state or an OFF-state at a gate-source voltage of zero. In enhancement mode devices, the devices are OFF at zero gate-source voltage, whereas in depletion mode devices, the device is ON at zero gate-source voltage. Conventional high performance Group III nitride-based HEMTs may typically be implemented as depletion mode (normally-on) devices, in that they are conductive at a gate-source bias of zero due to the polarization-induced charge at the interface of the barrier and channel layers of the device.

When a HEMT device is in an ON-state, a two-dimensional electron gas (2DEG) is formed at the heterojunction of two semiconductor materials with different bandgap energies, where the smaller bandgap material has a higher electron affinity. The 2DEG is an accumulation layer in the undoped (“unintentionally doped”) smaller bandgap material and can contain a very high sheet electron concentration. Additionally, electrons that originate in the wider-bandgap semiconductor material transfer to the 2DEG layer, allowing high electron mobility due to reduced ionized impurity scattering. This combination of high carrier concentration and high carrier mobility can give the HEMT a very large transconductance (which may refer to the relationship between output current and input voltage) and may provide a strong performance advantage over MOSFETs for high-frequency applications.

High electron mobility transistors fabricated in Group III-nitride based material systems also have the potential to generate large amounts of radio frequency (RF) power because of the combination of material characteristics that includes the aforementioned high breakdown fields, wide bandgaps, large conduction band offset, and/or high saturated electron drift velocity. As such, Group III-Nitride based HEMTs may be promising candidates for high power RF applications, as well as for low frequency high power switching applications.

Group III-Nitride based HEMTs that are provided in RF-based environments, such as RF monolithic microwave integrated circuits (MMICs), may include on-chip resistors that control the RF signal path, provide impedance matching, and/or provide other RF circuit functionality. As an example, RF MMICs may include on-chip resistors (e.g., an n-type GaN-based on-chip resistor) having a sheet resistance of about 60 ohm/square to about 90 ohm/square.

### SUMMARY

According to some embodiments, a semiconductor device includes a semiconductor structure comprising first and second semiconductor layers having different bandgaps, first and second contacts on the semiconductor structure and free of a gate structure therebetween, and a resistor comprising a portion of the semiconductor structure that electrically connects the first and second contacts.

In some embodiments, the portion of the semiconductor structure comprises a second portion of the second semiconductor layer that is recessed in thickness relative to a first portion thereof.

In some embodiments, the first portion of the second semiconductor layer has a first electrical resistance associated therewith, and the second portion of the second semiconductor layer has a second electrical resistance associated therewith that is higher than the first electrical resistance.

In some embodiments, ohmic contact elements are provided on the second portion of the second semiconductor layer and electrically coupling the first and second contacts to the second portion of the second semiconductor layer.

In some embodiments, a passivation layer is provided on the portion of the semiconductor structure and in direct contact with the second semiconductor layer.

In some embodiments, the portion of the first semiconductor layer extends between non-conductive regions of the semiconductor structure.

In some embodiments, the first and second contacts extend onto the non-conductive regions of the semiconductor structure.

In some embodiments, a thickness of the second portion is greater than about 2 nanometers (nm).

In some embodiments, the second portion has one or more lateral dimensions of about 0.25 microns to about 1000 microns.

In some embodiments, the first and second semiconductor layers comprise group III-nitride-based materials, the second semiconductor layer comprises an aluminum composition of about 20 to about 35 percent, and the thickness of the second portion is about 5 nanometers (nm) to about 10 nm.

In some embodiments, source and drain contacts and a gate therebetween are provided on an active region of the semiconductor structure, where the active region comprises at least one transistor. The portion of the semiconductor structure continuously extends from the first contact to the second contact outside of the active region.

In some embodiments, the resistor comprises a portion of an impedance matching, harmonic termination, or bias control circuit of the at least one transistor outside the active region.

In some embodiments, the semiconductor device is a passive device and the semiconductor structure is free of transistors.

In some embodiments, the resistor has a sheet resistance of about 300 ohm/square to about 2500 ohm/square.

According to some embodiments, a semiconductor device includes a semiconductor structure comprising a heterojunction between first and second semiconductor layers, and an integrated resistor in the semiconductor structure. The integrated resistor has a sheet resistance of about 300 ohm/square to about 2500 ohm/square.

In some embodiments, first and second contacts are provided on the semiconductor structure and free of a gate structure therebetween, and the integrated resistor comprises a portion of the semiconductor structure that electrically connects the first and second contacts.

In some embodiments, the portion of the semiconductor structure comprises a second portion of the second semiconductor layer that is recessed in thickness relative to a first portion thereof.

In some embodiments, the second portion of the second semiconductor layer extends between non-conductive regions of the semiconductor structure.

In some embodiments, the first and second contacts extend onto the non-conductive regions of the semiconductor structure and are electrically coupled to the second portion of the second semiconductor layer.

In some embodiments, ohmic contact elements are provided on the second portion of the second semiconductor layer and electrically coupling the second portion of the second semiconductor layer to the first and second contacts.

In some embodiments, a thickness of the second portion is greater than about 2 nanometers (nm).

In some embodiments, a passivation layer is provided on the portion of the semiconductor structure and in direct contact with the second semiconductor layer.

According to some embodiments, a semiconductor device includes a semiconductor structure comprising a heterojunction between a channel layer and a barrier layer thereon, first and second contacts on the semiconductor structure and free of a gate structure therebetween, and an integrated resistor comprising a second portion of the barrier layer that extends between the first and second contacts and is recessed in thickness relative to a first portion thereof.

In some embodiments, the first portion of the barrier layer has a first electrical resistance associated therewith, and the second portion of the barrier layer has a second electrical resistance associated therewith that is higher than the first electrical resistance.

In some embodiments, a thickness of the second portion is greater than about 2 nanometers (nm).

In some embodiments, the second portion has one or more lateral dimensions of about 0.25 microns to about 1000 microns.

In some embodiments, the channel layer and the barrier layer comprise group III-nitride-based materials, the barrier layer comprises an aluminum composition of about 20 to about 35 percent, and the thickness of the second portion is about 5 nanometers (nm) to about 10 nm.

According to some embodiments, a semiconductor device includes a semiconductor structure comprising a heterojunction between a channel layer and a barrier layer thereon, first and second contacts on the semiconductor structure and free of a gate structure therebetween, a passivation layer directly on a portion of the barrier layer between the first and second contacts, and an integrated resistor that electrically connects the first and second contacts and comprises the portion of the barrier layer having the passivation layer thereon.

In some embodiments, the portion of the barrier layer is a second portion thereof, and the second portion of the barrier layer has a higher electrical resistance associated therewith than that of first portions thereof adjacent the first and second contacts.

In some embodiments, the channel layer and the barrier layer comprise group III-nitride-based materials, the barrier layer comprises an aluminum composition of about 20 to about 35 percent, and the passivation layer comprises silicon nitride.

According to some embodiments, a method of fabricating a semiconductor device includes providing a semiconductor structure comprising first and second semiconductor layers having different bandgaps, performing a looped recess process to recess a thickness of a second portion of the second semiconductor layer relative to a first portion thereof, and forming first and second contacts on the semiconductor structure. The second portion of the second semiconductor layer comprises an integrated resistor that electrically connects the first and second contacts.

In some embodiments, the integrated resistor has a sheet resistance of about 300 ohm/square to about 2500 ohm/square.

In some embodiments, the first portion of the second semiconductor layer has a first electrical resistance associated therewith, and the second portion of the second semiconductor layer has a second electrical resistance associated therewith that is higher than the first electrical resistance.

In some embodiments, the looped recess process comprises a plurality of loops that are configured to remove, layer-by-layer, the second portion of the second semiconductor layer.

In some embodiments, the looped recess process is a plasma etch process, and each of the loops is configured to remove a monolayer of the second semiconductor layer.

In some embodiments, each of the loops comprises an adsorption process and a desorption process with a purge process therebetween.

In some embodiments, the adsorption process is chlorine-based, the desorption process is argon-based, and the purge process is helium- or nitrogen-based.

In some embodiments, the first semiconductor layer and the second semiconductor layer comprise a group III nitride-based material, and the second semiconductor layer has a higher bandgap than that of the first semiconductor layer.

In some embodiments, a surface roughness along the second portion of the second semiconductor layer is less than about 3 Angstroms (Å).

According to some embodiments, a method of fabricating a semiconductor device includes providing a semiconductor structure comprising first and second semiconductor layers having a heterojunction therebetween, forming a passivation layer directly on a portion of the second semiconductor layer, and forming first and second contacts on the semiconductor structure. The portion of the second semiconductor layer having passivation layer thereon comprises an integrated resistor that electrically connects the first and second contacts free of a gate electrode therebetween.

In some embodiments, the method further includes performing a surface preparation process on the portion of the second semiconductor layer prior to forming the passivation layer thereon. The surface preparation process is configured to locally reduce a carrier density between the portion of the second semiconductor layer and the first semiconductor layer.

In some embodiments, the surface preparation process comprises a wet cleaning process or a plasma process.

In some embodiments, the first semiconductor layer and the second semiconductor layer comprise a group III nitride-based material, the passivation layer comprises silicon nitride, and forming the passivation layer comprises adjusting component ratios of silicon and nitride and/or a bulk dielectric charge density of the passivation layer.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the disclosure, and be protected by the accompanying claims.

### BRIEF DESCRIPTION OF THE DRAWINGS

FIG. 1A is a schematic cross-sectional view illustrating a portion of an example integrated resistor according to some embodiments of the present disclosure.

FIG. 1B is a schematic cross-sectional view illustrating a portion of another example integrated resistor according to some embodiments of the present disclosure.

FIG. 2 is a schematic cross-sectional view illustrating an example semiconductor device including integrated resistors according to some embodiments of the present disclosure.

FIG. 3 is a graph illustrating a relationship between sheet resistance and thickness of one or more semiconductor layers of an integrated resistor according to some embodiments of the present disclosure.

FIGS. 4A-4B, 5A-5B, 6A-6B, 7A-7B, and 8A-8B are schematic diagrams illustrating methods of locally controlling sheet resistance of an integrated resistor using a looped recess process according to some embodiments of the present disclosure.

FIG. 9 is a schematic plan view of a Group III nitride-based transistor die according to embodiments of the present disclosure.

FIG. 10A is a schematic side view of a packaged Group III nitride-based RF transistor amplifier that includes integrated resistors according to embodiments of the present disclosure.

FIG. 10B is a schematic side view of a packaged Group III nitride-based RF transistor amplifier that includes integrated resistors packaged in a printed circuit board based package structure according to embodiments of the present disclosure.

FIG. 10C is a schematic side view of another packaged Group III nitride-based RF transistor amplifier that includes integrated resistors according to embodiments of the present disclosure.

FIG. 11A is a schematic cross-sectional view illustrating a packaged integrated resistor according to some embodiments of the present disclosure.

FIG. 11B is a schematic cross-sectional view illustrating another example packaged integrated resistor according to some embodiments of the present disclosure.

### DETAILED DESCRIPTION OF EMBODIMENTS

Some embodiments may arise from realization that it larger sheet resistances may be desirable for certain components of the RF MMIC (e.g., a control circuit or a switch driver) and for certain high frequency applications, such as larger than 300 ohm/square (e.g., 500 ohm/square to about 1200 ohm/square). However, some conventional materials employed for on-chip resistors may not be compatible with high high-volume manufacturing processes for microelectronics. For example, some conventional materials may not be sufficiently thick and/or may have a higher intrinsic resistivity, thereby inhibiting the efficiency, control, and repeatability of high-volume manufacturing processes (e.g., conventional etching processes).

Embodiments of the present disclosure provide resistors that are integrated with a semiconductor structure (e.g., on-die resistors), also referred to herein as integrated resistors. In particular, some embodiments may provide integrated resistors in heterojunction-based semiconductor structures (i.e., having first and second stacked layers having different bandgaps), such as Group III-nitride-based heterojunction structures. The integrated resistors may be included in the same semiconductor die as one or more transistors, or may be implemented as standalone components that are free of transistors (e.g., IPD or SMD components).

In some embodiments, the integrated resistor may be formed with a desired resistance value by locally reducing or recessing the thickness of a portion of the semiconductor structure. For example, atomic layer etching (ALE) may be used to remove precise thicknesses of a barrier layer of a semiconductor heterostructure in specific locations, thereby locally decreasing the underlying 2DEG charge carrier concentration and increasing the effective sheet resistance (Rsheet). Such methods may be compatible with high-volume manufacturing (HVM) processes, achieve resistance values that were previously unachievable (e.g., by locally controlling the thicknesses of one or more layers of the semiconductor heterojunction structures, in some embodiments with monolayer precision), and allow for a variety of high frequency RF applications. Applying atomic layer etching in some embodiments as described herein may use the intrinsic precision that is inherent to the monolayer removal process to achieve resistance values and/or other capabilities heretofore unavailable for RF MMIC designers. Additionally, using ALE in a separate resistor fabrication step or process to locally recess the thickness of the barrier layer in regions of the semiconductor structure outside of the active channel region may allow the full thickness of the barrier layer to be maintained in the active region, thereby retaining desired RF performance of the transistors on the semiconductor structure.

In some embodiments, the integrated resistor may be provided with a desired resistance value by locally controlling surface characteristics of a portion of the semiconductor structure. For example, a surface preparation process may be locally performed on a portion of the semiconductor structure (e.g. on surfaces of the barrier layer) to locally reduce a carrier density at the heterointerface between the channel and barrier layers. Additionally or alternatively, a passivation layer may be locally formed on a portion of the semiconductor structure, where component ratios of elements of a passivation layer may be adjusted so as to achieve a desired bulk dielectric charge density.

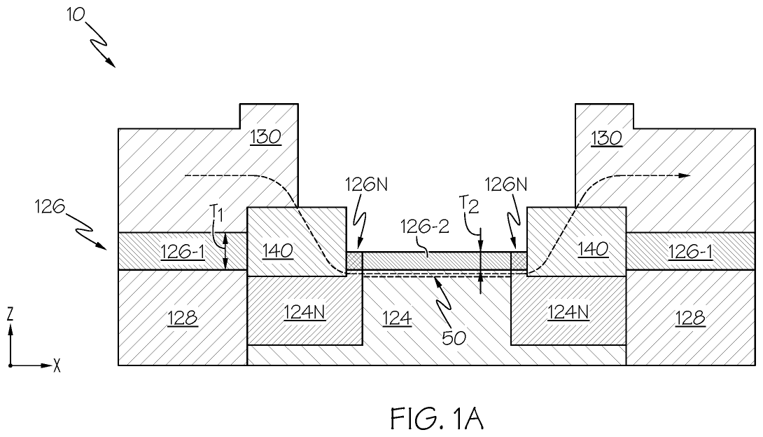

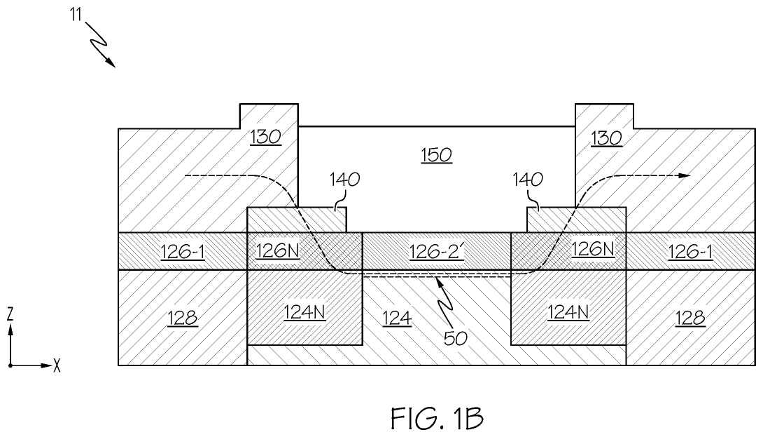

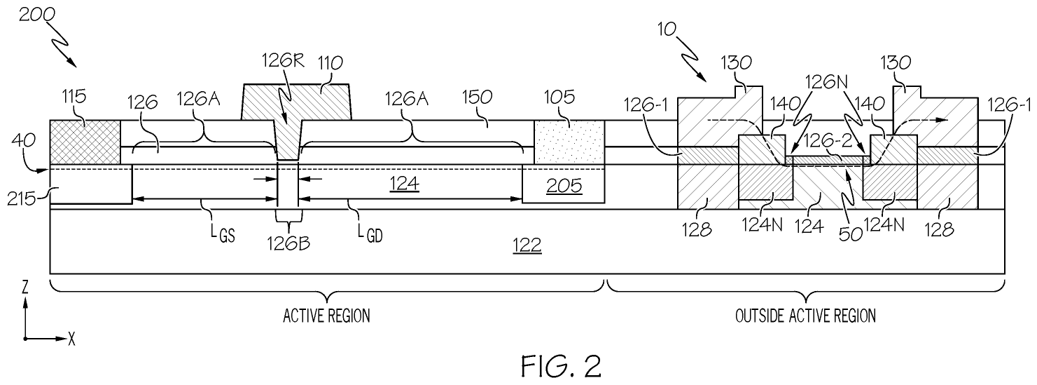

FIG. 1A is a schematic cross-sectional view illustrating a portion of a semiconductor device according to some embodiments of the present disclosure. Specifically, FIG. 1A illustrates a resistor that is integrated in a semiconductor structure, illustrated by way of example with reference to integrated resistor 10. The integrated resistor 10 may be Group-III nitride based, although other material systems can also be used. As noted above, Group III nitrides may refer to semiconductor compounds formed between nitrogen and the elements in the Group III of the periodic table, such as aluminum (Al), gallium (Ga), scandium (Sc), and/or indium (In), and may form binary (e.g., GaN), ternary (e.g., AlGaN, AlInN), and quaternary (e.g., AlInGaN) compounds. Accordingly, formulas such as AlₓGa₁₋ₓN, where 0≤x≤1, may be used to describe these compounds. However, while described herein primarily with reference to GaN channel layers 124 and AlGaN barrier layers 126 by way of example, it will be understood that other Group IIIa or IIIb materials may be used. In one embodiment, the integrated resistor 10 includes a channel layer 124, a barrier layer 126, contacts 130, and ohmic contact elements 140. The integrated resistor 10 may be provided on a substrate, as described below in further detail with reference to FIG. 2. Furthermore, the integrated resistor 10 may not include a gate structure between the contacts 130 and/or the ohmic contact elements 140.

In some embodiments, the channel layer 124 may extend between non-conductive regions 128 of the semiconductor device (described below in further detail with reference to FIG. 2). The barrier layer 126 may be on the channel layer 124 and the non-conductive regions 128. The channel layer 124 may have a bandgap that is less than the bandgap of the barrier layer 126, and the channel layer 124 may also have a larger electron affinity than the barrier layer 126. At least one of the channel layer 124 and the barrier layer 126 may include sub-layers including doped or undoped (i.e., “unintentionally doped”) layers or regions of Group III-nitride materials, including material compositions that may be stepwise or continuously graded. In some embodiments, the channel layer 124 may be a multi-layer structure, such as a superlattice or combinations of GaN, AlGaN or the like. The channel layer 124 may be under compressive strain in some embodiments. The barrier layer 126 may comprise a single layer or may be a multi-layer structure. As an example, the channel layer 124 may include doped (e.g., n″) regions 124N between the non-conductive regions 128 of the semiconductor device. As another example, the barrier layer 126 may include doped (e.g., n″) regions 126N that extend from and/or adjacent to the ohmic contact elements 140. The doped regions 124N, 126N may have substantially similar doping concentrations, but it should also be understood that the doping concentrations may be unequal in other embodiments.

The barrier layer 126 may have a sufficient thickness, material composition, and/or doping to induce a carrier concentration (and an associated electrical resistance) at the interface between the channel layer 124 and the barrier layer 126 through polarization effects when the barrier layer 126 is buried under ohmic contact metal. In some embodiments, the barrier layer 126 may comprise a portion having a recessed thickness and different electrical resistance relative to other portions of the barrier layer 126. As an example, the barrier layer 126 may include first portions 126-1 on the non-conductive regions 128 and having a first thickness T₁ and configured to provide a first electrical resistance R₁, and the barrier layer 126 may include a second, recessed portion 126-2 (hereinafter “second portion 126-2”) on the channel layer 124 and having a second thickness T₂ and configured to provide a second electrical resistance R₂. The second thickness T₂ may be less than the first thickness T₁, and the second electrical resistance R₂ may be greater than the first electrical resistance R₁.

As noted above, a 2DEG conduction channel 50 is formed at the heterojunction between the smaller bandgap channel layer 124 and the wider bandgap barrier layer 126, where carriers that originate in the wider-bandgap barrier layer 126 may transfer to the 2DEG conduction channel 50. The respective thicknesses T₁, T₂ may thereby be selected to provide a desired carrier concentration (also referred to as carrier density) at the interface between the channel layer 124 and the portions 126-1, 126-2 of the barrier layer 126, thereby locally controlling the electrical resistance at the portions 126-1, 126-2. The thickness T₂ may have a minimum value (e.g., greater than about 2 nanometers (nm)) that is configured to provide a sufficient carrier density to maintain conduction between the contacts 130. The thickness T₂ may be selected to achieve a local reduction in carrier concentration (and a corresponding increase in sheet resistance) of the 2DEG conduction channel 50 at the recessed portion 126-2 of the barrier layer 126. As an example, the thickness value T₂ may be about 5 nm to about 10 nm. Additionally, the carrier concentration at the interface between the channel layer 124 and the barrier layer 126 may be based on the component composition of the barrier layer 126 (e.g., the aluminum (Al) composition for an AlGaN barrier layer). As an example, the barrier layer 126 may have an aluminum composition of about 20 to about 35 percent, but it should be understood that other composition ranges may be employed.

The contacts 130 may extend onto the non-conductive regions 128 and may include various suitable semiconductor metal contacts, such as a Schottky contact. Example Schottky contacts of a Group III nitride-based semiconductor material may include, for example, nickel (Ni), platinum (Pt), nickel silicide (NiSiₓ), copper (Cu), palladium (Pd), chromium (Cr), tungsten (W) and/or tungsten silicon nitride (WSiN).

The ohmic contact elements 140 include a metal that can form an ohmic contact to the channel layer 124 and the barrier layer 126. In some embodiments, the ohmic contact elements 140 may directly contact the contacts 130 and at least one of the channel layer 124 and the barrier layer 126 to thereby electrically couple the contacts 130 to the barrier layer 126. To form the ohmic contact elements 140, a conductive metal material may be deposited and annealed (e.g., at a temperature of about 600° C. to 1050° C.). Suitable metals may include refractory metals, such as titanium (Ti), tungsten (W), titanium tungsten (TiW), silicon (Si), titanium tungsten nitride (TiWN), tungsten silicide (WSi), rhenium (Re), Niobium (Nb), Ni, gold (Au), aluminum (Al), tantalum (Ta), molybdenum (Mo), NiSiₓ, titanium silicide (TiSi), titanium nitride (TIN), WSiN, Pt and the like.

In operation of some depletion mode devices as described herein, a two-dimensional electron gas (2DEG) channel 50 may be formed due to the polarization-induced charge at the heterojunction between the channel layer 124 and the barrier layer 126. The 2DEG channel 50 operates as a highly conductive channel that allows current to flow between the contacts 130 beneath the barrier layer 126. In particular, the channel layer 124 and the barrier layer 126 of the integrated resistor 10 may be formed of materials having different bandgaps such that a heterojunction is defined at an interface between the channel layer 124 and the barrier layer 126. The 2DEG conduction channel 50 is induced at the heterointerface between the channel layer 124 and the barrier layer 126, with the local thickness T₂ of the second portion 126-2 of the barrier layer 126 (and/or the composition thereof) controlling the carrier density of portions of the 2DEG conduction channel 50 to provide a desired resistance. That is, the 2DEG conduction channel 50 induced at the heterojunction between the channel layer 124 and the recessed portion 126-2 of the barrier layer 126 forms a resistive element between the contacts 130 (and/or the ohmic contact elements 140), where the resistive element has a resistance R₂ that is based on the thickness T₂ of the second portion 126-2 of the barrier layer 126 and/or the material composition of the second portion 126-2 of the barrier layer 126.

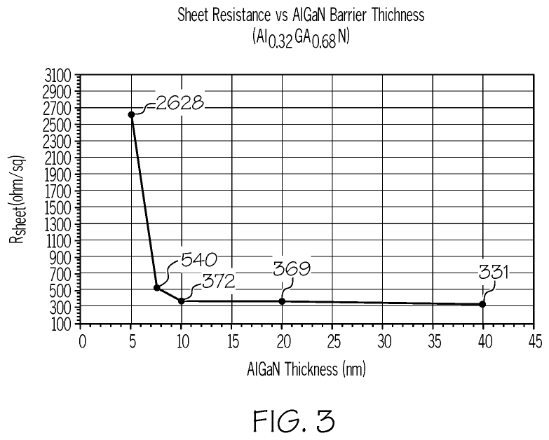

As an example, and referring to FIGS. 1A and 3, integrated resistors 10 including the resistive element may achieve sheet resistances in a range of about 300 ohm/square to about 2500 ohm/square (e.g., about 500 ohm/square to about 1200 ohm/square), which may be significantly greater than the range of sheet resistances achievable by some conventional on-die resistors (e.g., about 60 ohm/square to about 90 ohm/square). In some embodiments, the channel layer 124 and the barrier layer 126 may include group III-nitride materials, the barrier layer 126 may have an aluminum composition of about 20 to about 35 percent, for example, about 22 to about 25 percent. Specifically, in the example shown in the graph of FIG. 3 (illustrating effects on sheet resistance based on changes in thickness of an Al_{0.32}Ga_{0.68}N barrier), the sheet resistance may be about 2628 ohm/square when the thickness value T₂ is about 5 nm, 540 ohm/square when the thickness value T₂ is about 7.5 nm, about 372 ohm/square when the thickness value T₂ is about 10 nm, and about 331 ohm/square when the thickness value T₂ is about 40 nm. As the bandgap of the barrier layer 126 is increased (e.g., by increasing the Al composition) or decreased (e.g., by reducing the Al composition), the thickness of T₂ may be decreased or increased to achieve the desired sheet resistance, respectively. However, it will be understood that embodiments of the present disclosure are not limited to the illustrated ranges of sheet resistances, and it should be understood that other sheet resistance ranges may be provided in other embodiments, for example, depending on the composition of the barrier layer 126. Further control of sheet resistance may be achieved by altering other dimensions (e.g., the length and/or width, in addition to the thickness T₂) of the recessed portion 126-2 of the barrier layer 126, alone or in combination with altering the material compositions of the layers 124 and 126.

FIG. 1B is a schematic cross-sectional view illustrating another example portion of a semiconductor device according to some embodiments of the present disclosure. Specifically, FIG. 1B illustrates a resistor that is integrated with a semiconductor device, illustrated by way of example with reference to integrated resistor 11. The integrated resistor 11 is similar to the integrated resistor 10 described above with reference to FIG. 1A, but in this embodiment, the integrated resistor 11 further includes a passivation layer 150 provided between the contacts 130 and directly in contact with a portion 126-2′ of the barrier layer 126. The passivation layer 150 may be provided by one or more insulating materials (e.g., silicon nitride) and is configured to locally reduce the carrier density of the 2DEG conduction channel 50 of the portion 126-2′ of the barrier layer 126. For example, the passivation process used to form the passivation layer (e.g., the component element ratio and/or the bulk dielectric charge) may be modified to provide additional surface charge control at the portion 126-2′ of the barrier layer 126. The passivation layer 150 may be formed to provide surface charge control instead of or in combination with the carrier density control provided by the recessed portion 126-2 of the barrier layer 126. Additional surface charge control may be provided by performing surface preparation processes (e.g., wet cleaning steps and/or exposure to energetic species (such as remote nitrogen plasma) on the portion 126-2′ of the barrier layer 126 prior to deposition of the passivation layer 150 thereon. That is, by appropriately controlling the dimensional, physical, and/or chemical characteristics of the passivation layer 150 and/or the portion 126-2′ of the barrier layer 126 on which the passivation layer 150 is directly formed, the 2DEG conduction channel 50 at the portion 126-2′ of the barrier layer 126 may be configured to provide a sheet resistance in a range of about 300 ohm/square to about 2500 ohm/square.

The integrated resistors 10, 11 described herein may be coupled to a power transistor device and comprise at least a portion of an impedance matching circuit, a harmonic termination circuit, or a bias control circuit of a transistor structure outside an active region, as described below in further detail with reference to FIG. 2. That is, the integrated resistors 10, 11 may operate as resistive elements of an RF MMIC or other Group III-Nitride based HEMTs having suitable sheet resistances for various RF operations. Furthermore, the integrated resistors 10, 11 and the transistor structures may be provided on the same die to reduce the size and/or area of the RF MMIC and/or the corresponding electronic package.

Specifically, FIG. 2 is a schematic cross-sectional view illustrating the integrated resistor 10 and a transistor device according to some embodiments of the present disclosure, illustrated by way of example with reference to transistor structures 200 (also referred to herein as a transistor structure or transistor cell) of a transistor device, such as a HEMT. It should be understood that the integrated resistor 10 may be replaced with the integrated resistor 11 in other embodiments. In some embodiments, the transistor structure 200 and the integrated resistor 10, 11 may be collectively referred to herein as a “semiconductor device.”

As shown in FIG. 2, the transistor structure 200 and the integrated resistor 10 are formed on a substrate 122 such as, for example, a silicon carbide substrate. Hundreds or thousands of unit cell transistor structures 200 and/or integrated resistors 101 may be formed on the semiconductor substrate 122, and may be electrically connected (e.g., in parallel) to provide the semiconductor device. The substrate 122 may be a semi-insulating silicon carbide substrate, such as the 4H polytype of silicon carbide. Other silicon carbide candidate polytypes may include the 3C, 6H, and 15R polytypes. Although silicon carbide may be used as a substrate material, embodiments of the present disclosure may utilize any suitable substrate, such as sapphire (Al₂O₃), aluminum nitride (AlN), aluminum gallium nitride (AlGaN), gallium nitride (GaN), silicon (Si), GaAs, LGO, zinc oxide (ZnO), LAO, indium phosphide (InP), and the like. The substrate 122 may be a SiC wafer, and the semiconductor device may be formed, at least in part, via wafer-level processing. The wafer may then be diced or otherwise singulated to provide a multiple dies, where each die includes a plurality of the unit cell transistor structures 200.

In one embodiment, the channel layer 124, the barrier layer 126, and the passivation layer 150 are provided within both the active region (i.e., the location on the substrate 122 in which the transistor structure 200 is provided) and outside of the active region (i.e., the location on the substrate 122 in which the integrated resistor 10 is provided). The channel layer 124 of the active region and the area outside the active region may be physically and electrically isolated by the non-conductive regions 128 of the integrated resistor 10.

Source and drain electrodes (also referred to herein as source and drain contacts) 115 and 105 are formed laterally (e.g., along the X-direction) spaced apart from each other in the active region. The source contact 115 and the drain contact 105 may form ohmic contact to the barrier layer 126 or to the channel layer 124.

The one or more passivation layers 150 in the active region are formed on the barrier layer 126, and a gate contact (or simply “gate”) 110 is formed on the barrier layer 126 between the source and drain contacts 115 and 105. The gate 110 may be formed closer to the source contact 115, such that the gate-to-source length Los may be smaller than the gate-to-drain length LGD in some embodiments. Depending on configuration, one or more of the passivation layers 150 in the active region may be formed before and/or after formation of the gate 110.

The channel layer 124 and barrier layer 126 in both the active region and outside the active region may together define a semiconductor structure 190, with the source contact 115, the drain contact 105, and the gate 110 formed on the semiconductor structure 190. In the illustrated examples, the semiconductor structure 190 may be a semiconductor layer structure including one or more layers formed by epitaxial growth, and thus include one or more epitaxial layers 124, 126. Techniques for epitaxial growth of Group III nitrides have been described in, for example, U.S. Pat. Nos. 5,210,051, 5,393,993, and 5,523,589, the disclosures of which are also incorporated by reference herein in their entireties.

While the semiconductor structure 190 is shown with reference to one or more epitaxially grown channel and barrier layers 124, 126 for purposes of illustration, the semiconductor structure 190 may include additional layers/structures/elements in the active region or outside of the active region, such as isolation layer(s), buffer and/or nucleation layer(s) on or between substrate 122 and the one or more channel layers 124, and/or a cap layer on an upper surface of the barrier layer 126. For example, an AlN buffer layer may be formed on the upper surface of the substrate 122 to provide an appropriate crystal structure transition between the silicon carbide substrate 122 and the remainder of the layers of the semiconductor structure 190. Additionally, strain balancing transition layer(s) may also and/or alternatively be provided in the active region or outside of the active region. The optional buffer/nucleation/transition layers, as well as the channel layer 124 and/or the barrier layer 126, may be deposited, for example, by metal-organic chemical vapor deposition (MOCVD), molecular beam epitaxy (MBE), and/or hydride vapor phase epitaxy (HVPE).

The material of the gate 110 may be chosen based on the composition of the semiconductor structure 190, and may, in some embodiments, be a Schottky contact. Some materials capable of making a Schottky contact to a Group III nitride-based semiconductor material that may be used as the gate 110 may include, for example, nickel (Ni), platinum (Pt), nickel silicide (NiSiₓ), copper (Cu), palladium (Pd), chromium (Cr), tungsten (W) and/or tungsten silicon nitride (WSiN).

The source contact 115 and/or the drain contact 105 may include a metal that can form an ohmic contact to the semiconductor material of the structure 190. For example, a conductive metal material may be deposited and annealed (e.g., at a temperature of about 600° C. to 1050° C.) to form the ohmic contacts. Suitable metals may include refractory metals, such as Ti, W, titanium tungsten (TiW), silicon (Si), titanium tungsten nitride (TiWN), tungsten silicide (WSi), rhenium (Re), Niobium (Nb), Ni, gold (Au), aluminum (Al), tantalum (Ta), molybdenum (Mo), NiSiₓ, titanium silicide (TiSi), titanium nitride (TiN), WSIN, Pt and the like. Thus, the source contact 115 and/or the drain contact 105 may contain an ohmic contact portion in direct contact with the layer 124 and/or 126. In some embodiments, the source contact 115 and/or the drain contact 105 may be formed of a plurality of layers to form an ohmic contact that may be provided as described, for example, in commonly assigned U.S. Pat. No. 8,563,372 and U.S. U.S. Pat. No. 9,214,352, the disclosures of which are hereby incorporated herein in their entirety by reference.

In operation, a 2DEG channel 40, 50 may be formed at a junction between the channel layer 124 and the barrier layer 126 in the active region when the semiconductor device is biased to be in its conducting or “on” state. The 2DEG channel 40 acts as a highly conductive channel that allows current to flow between the source and drain regions 215 and 205 that are beneath the source contact 115 and the drain contact 105, respectively. The 2DEG channel 50 similarly acts as a conductive channel (albeit with increased resistance, as described herein) that allows current to flow between the regions 124N that are beneath the first and second contacts 130/140, respectively. In particular, the channel layer 124 and the barrier layer 126 of the semiconductor structure 190 may be formed of materials having different bandgaps, such that a heterojunction is defined in the active region at an interface between the channel layer 124 and the barrier layer 126. The 2DEG conduction channel 40, 50 can be induced at the heterointerface between the channel layer 124 and the barrier layer 126. The channel layer 124, 2DEG conduction channel 40, and barrier layer 126 can generally form the active region of the HEMT device. The channel layer 124, 2DEG conduction channel 50, and barrier layer 126 can generally form the integrated resistor 10 (or 11) outside the active region of the HEMT device. It should be noted that while described herein primarily with reference to fabrication and structures of HEMT devices, the elements and concepts of embodiments described herein can be applied to many different types of transistor structures.

In some embodiments, the semiconductor structure 190 is a gallium-based semiconductor structure that is formed on the substrate 122 (e.g., a silicon carbide substrate). As used herein, the term “gallium-based” refers to semiconductor compounds that include at least gallium, for example, GaN or GaAs. In some embodiments, the gallium-based semiconductor structure 190 may include, for example, a gallium nitride-based channel layer 124 (e.g., a GaN channel layer) and a gallium nitride based-barrier layer 126 (e.g., an AlGaN barrier layer) that is formed on the gallium nitride-based channel layer 124 opposite the substrate 122. Gallium nitride-based semiconductor structures 190 may include at least gallium and nitrogen, including gallium nitride (GaN) as well as ternary and quaternary compounds such as aluminum gallium nitride (AlGaN) and aluminum indium gallium nitride (AlInGaN).

A plurality of enhancement and/or depletion mode transistor devices 200 may be formed on and in the gallium-based semiconductor structure 190. The source and drain contacts 115 and 105 may be formed on the semiconductor structure 190, and the gate may be formed on the barrier layer 126 between the contacts 115 and 105. For example, the source and the drain contacts 115 and 105 may be formed as ohmic contacts (e.g., on implanted regions 215 and 205 in the channel layer 124) such that an electric current flows between the source and drain contacts 115 and 105 via the 2DEG channel 40 induced at the heterointerface between the channel layer 124 and barrier layer 126 when the gate 110 is biased at an appropriate level.

In some devices, a portion 126B of the gallium-based barrier layer 126 that is between the source and drain contacts 115 and 105 may be at least partially etched to form a gate opening 126R (also referred to herein as the gate recess) in the barrier layer 126, and the gate 110 may be formed in the gate recess 126R. As such, the portion 126B of the barrier layer 126 under the gate 110 (i.e., extending between the gate 110 and the channel layer 124; also referred to as the gate region 126B) may have a thickness that is less than a thickness of portions of the barrier layer 126 between the gate 110 and the source contact 115 or the drain contact 105. The region between the gate 110 and the source contact 115 (and the region between the gate 110 and the drain contact 105) may be referred to herein as access regions, or source/drain access regions. Additional details regarding the gate recess and the formation thereof are provided in, for example, U.S. patent application Ser. No. 17/834,144, the disclosure of which is also incorporated by reference herein in its entirety.

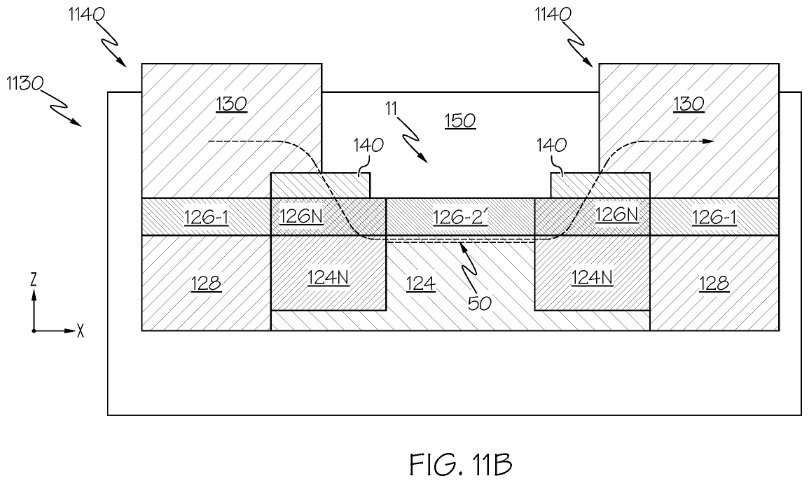

While the integrated resistors 10, 11 are shown as being integrated with the transistor structure 200, it should be understood that the integrated resistors 10, 11 may be provided as standalone devices that are not provided on the substrate 122 of the transistor structure 200 (or may be provided on respective substrates that are distinct from the substrate 122 of the transistor structure 200). As an example, and as shown in FIG. 11A, the integrated resistor 10 may be at least partially within a housing 1110 having openings 1120 in which the contacts 130 are provided and exposed, thereby enabling the integrated resistor 10 to be electrically and physically coupled to an external electronic device or system. As another example, and as shown in FIG. 11B, the integrated resistor 11 may be at least partially within a housing 1130 having openings 1140 in which the contacts 130 are provided and exposed, thereby enabling the integrated resistor 11 to be electrically and physically coupled to an external electronic device or system. The housings 1110, 1130 may be provided as an overmold structure (e.g., formed of an encapsulant material, such as a plastic, or resin), or may be provided as an open-cavity structure (e.g., a ceramic structure having a ceramic lid and ceramic sidewalls that collectively define a cavity). The integrated resistors 10, 11 may thereby be implemented as standalone components (e.g., IPD or SMD components) that are free of transistors within the housings 1110, 1130.

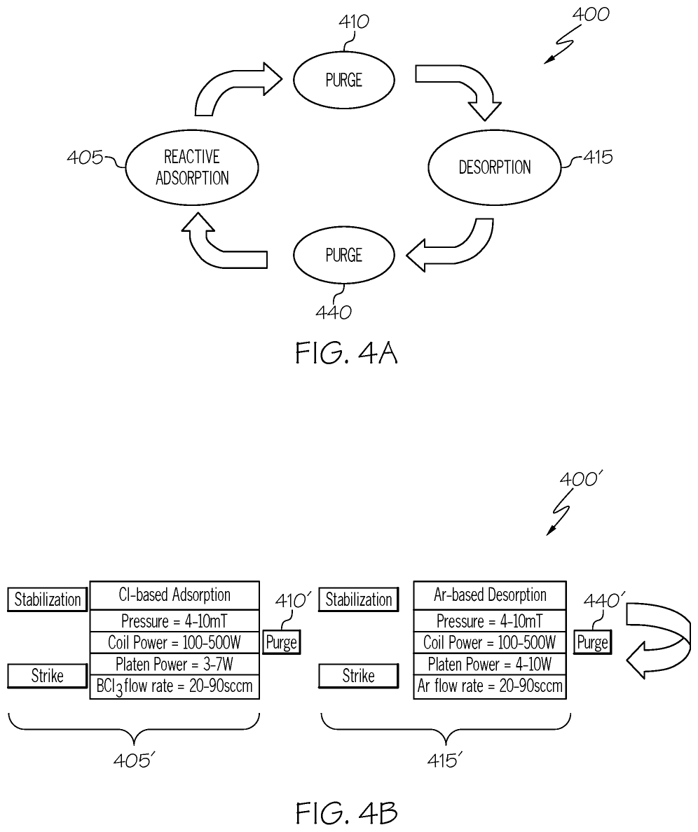

FIGS. 4A and 4B are schematic diagrams illustrating methods of forming the recessed portion 126-2 of the integrated resistor 10 using a looped recess process according to some embodiments of the present disclosure. As shown in FIGS. 4A and 4B, embodiments of the present disclosure provide a looped recess process 400, 400′ that allows for layer-by-layer removal of a portion of a barrier layer 126 located outside of the active region and within the integrated resistor 10 to define the recessed portion 126-2 as described herein. The looped recess process 400, 400′ may likewise be used to form the gate recess 126R of the transistor structure 200 in the active region, e.g., either in conjunction with or independently of the looped recess process used in forming the recessed portion 126-2 of the integrated resistor 10. The looped recess process 400, 400′ may be a plasma etch process, where each of the loops is configured to remove a monolayer of the barrier layer 126.

FIG. 4A illustrates that each loop of the plasma etch process 400 includes a reactive (e.g., chlorine (Cl)-based) adsorption operation 405 and a low power (e.g., argon (Ar)-based) desorption operation 415, with purge operations 410, 440 (e.g., helium (He)- or nitrogen (N)-based) therebetween. The operations 405, 410, 415, 440 may be repeated or “looped” to provide layer-by-layer removal of the barrier layer 126 until a desired thickness value T₂ of the recessed portion 126-2 is achieved.

FIG. 4B illustrates example parameters for a plasma etch process 400′ in greater detail. In the operations 400′, a Ga-based semiconductor wafer (e.g., the substrate 122 including a GaN channel layer 124 and an AlGaN barrier layer 126) may be mounted on a chuck provided inside a chamber of an inductively coupled plasma (ICP) etching apparatus. The chamber may include a platen and may be surrounded by a coil. Power applied to the coil may generate plasma from a gas introduced into the chamber, while power applied to the platen may affect ion flux and speed at which the ions are accelerated toward the surface to be etched (e.g., the exposed surface of the AlGaN barrier layer 126).

In particular, in operation 405′, a reactant gas (e.g., Cl) is introduced into the chamber (e.g., at a pressure of about 4 to 10 mTorr, such as about 6 mTorr or about 8 mTorr), for example, with a flow rate of about 20 to 90 sccm (e.g., about 30 sccm, about 50 sccm, or about 70 sccm). High frequency (RF) power (e.g., at about 100 W to 500 W, such as about 200 W, about 300 W, or about 400 W) is applied to a coil of the ICP etching apparatus, which induces an electromagnetic current that acts on the reactant gas to generate a plasma for the adsorption process. For example, operation 405′ may include chlorinating the surface of AlGaN barrier layer (e.g., with a Cl-based gas, such as Cl₂ or boron trichloride (BCl₃)). The adsorption process 405′ may be performed using coil power only (i.e., without ion driving/platen power) or at a relatively low platen power (for example, at about 3 W to 7 W), which may promote primarily chemical reactive adsorption of Cl on the exposed Ga-based surface. In operation 410′, a purge process is performed by introducing a purge gas (e.g., He or N) into the chamber to evacuate the reactant gas.

In operation 415′, an etchant gas (e.g., Ar) is introduced into the chamber (e.g., at a pressure of about 4 to 10 mTorr, such as about 6 mTorr, about 8 mTorr, or about 10 mTorr), for example, with a flow rate of about 20 to 90 sccm (e.g., about 30 sccm, about 50 sccm, or about 70 sccm). High frequency (RF) power (e.g., at about 100 W to 500 W, such as about 200 W, about 300 W, or about 400 W) is applied to a coil of the ICP etching apparatus to induce an electromagnetic current that acts on the etchant gas to generate a plasma for the desorption process. For example, operation 415′ may include an argon-based ion milling operation that results in the desorption of the volatile etch by-product. The desorption process 415′ may be performed at a relatively low platen power (for example, at about 4 W to 10 W, e.g., about 6 W or about 8 W), with a controlled peak-to-peak voltage to produce substantially uniform incident ion energy. The peak-to-peak voltage may refer to the magnitude of the RF voltage at the surface of the platen.

In operation 440′, another purge process is performed by introducing a purge gas (e.g., He or N) into the chamber to evacuate the etchant gas. The operations 405′, 410′, 415′, and 440′ are looped until a desired thickness value T₂ of the recessed portion 126-2 is achieved by the looped recess process 400′.

While described herein with respect to a looped recess process 400′ including a Cl-based adsorption process 405′ and an Ar-based desorption process 415′, it will be understood that adsorption 405 and desorption 415 processes as described herein are not limited to these elements. For example, O₂-based adsorption 405 and BCl₃-based desorption 410 loops may also be used. More generally, for example, the ALE process 400 may be terminated with any plasma chemistry, including (but not limited to) O₂, Cl, He, F. In some embodiments, one or more parameters of the looped recess process 400, 400′ may be defined to ensure monolayer removal, e.g., to account for ICP tool variation.

That is, FIGS. 4A and 4B are described herein with reference to methods of removing portions of an AlGaN barrier layer using a looped plasma process to effectively achieve atomic layer etching using an ICP tool, but it will be understood that embodiments of the present disclosure are not limited to the particular materials and/or tools described herein and may be similarly applied to other materials and/or tools. For example, layer-by-layer removal of other Ga-based layers may be performed using a looped Cl adsorption and Ar desorption process and parameters as shown in FIGS. 4A and 4B.

The looped recess process 400, 400′ described herein can thus be used in the fabrication of the integrated resistor 10 to selectively etch the recessed portion 126-2 in the barrier layer 126 with greater control of the thickness value T₂ of the recessed portion 126-2 and improved surface characteristics of the recessed portion 126-2 than some conventional plasma-based etching. The looped recess process as described herein may allow for controlled, layer-by-layer localized removal of the barrier layer 126 to form the portion 126-2 to a desired thickness T₂ or depth (as measured from a surface of the barrier layer 126 opposite the channel layer 124), with limited effect on the surface states of the etched portion 126B of the barrier layer 126. For example, in some embodiments, the looped recess process 400, 400′ may provide a surface roughness (a root mean square (RMS) surface roughness (Rq) or an average surface roughness (Ra) per unit area) of less than about 3 Å (e.g., about 1 Å to 2 Å) along a surface (e.g., a floor) of the recessed portion 126-2. The controlled, layer-by-layer localized removal may form the portion 126-2 to a thickness T₂ as low as a minimum critical thickness to maintain conduction (e.g., as low as about 2 nm). In some embodiments, the looped recess process 400, 400′ may form the portion 126-2 of the barrier layer 126 with a thickness T₂ of about 5 nm to about 10 nm, for example, for group-III nitride-based barrier layer 126 having an Al composition of between about 20 to about 35 percent.

The looped recess process 400, 400′ may also be used in conjunction with one or more masking steps to control one or more lateral dimensions (e.g., in directions perpendicular to or otherwise different than the thickness dimension) of the recessed portion 126-2 of the barrier layer 126 to achieve the desired resistance. In some embodiments, the portion 126-2 may have one or more lateral dimensions of between about 0.25 microns to about 1000 microns. That is, looped recess processes in accordance with some embodiments of the present disclosure may be used to precisely scale the thickness T₂ of the recessed portion 126-2 of the barrier layer 126 with one or more lateral dimensions of the recessed portion 126-2. Controlling the thickness T₂ of the recessed portion 126-2 (alone or in combination with the lateral dimensions and/or the material composition thereof) may be critical to achieving the sheet resistance ranges of about 300 ohm/square to about 2500 ohm/square (e.g., about 500 ohm/square to about 1200 ohm/square) as described herein. Also, while illustrated with reference to forming a single recess 126-2, it will be understood that multiple recesses 126-2 (and thus, multiple integrated resistors) may be simultaneously or sequentially formed by performing the looped recess process 400, 400′ in different regions of the barrier layer 126.

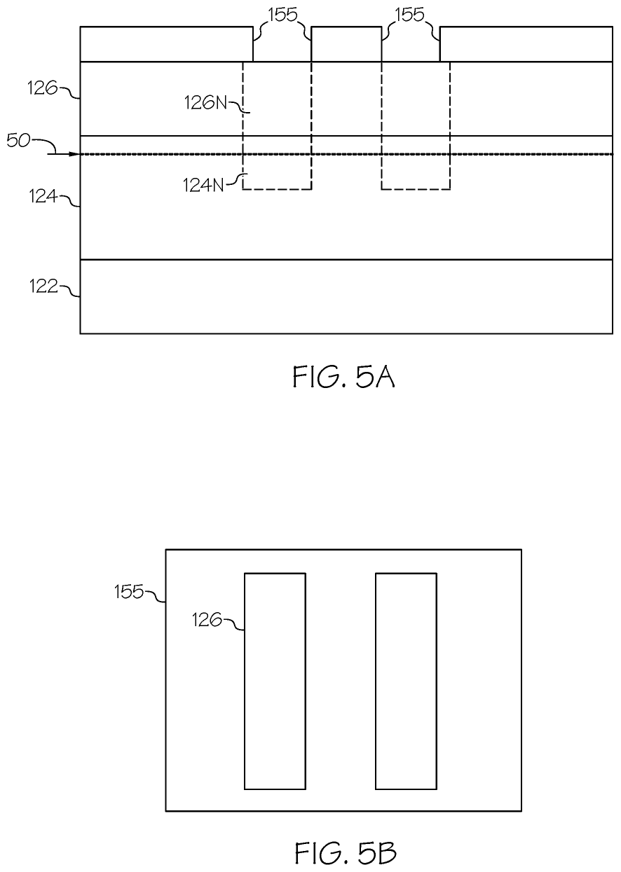

FIGS. 5A-5B, 6A-6B, 7A-7B, and 8A-8B are schematic cross-sectional and top or plan views illustrating methods of forming the recessed portion 126-2 of the integrated resistor 10 using looped recess processes according to various embodiments of the present disclosure. As shown in FIGS. 5A-5B, the barrier layer 126 and the channel layer 124 are provided on the substrate 122. As an example, the channel layer 124 and the barrier layer 126 are epitaxially grown on the substrate, as described in, for example, U.S. Pat. Nos. 5,210,051, 5,393,993, and 5,523,589, the disclosures of which are also incorporated by reference herein in their entireties. As another example, the channel layer 124 and the barrier layer 126 may be deposited on the substrate 122 by, for example, metal-organic chemical vapor deposition (MOCVD), molecular beam epitaxy (MBE), and/or hydride vapor phase epitaxy (HVPE). Subsequently, a mask 155 (e.g., a patterned photoresist mask) is formed on the barrier layer 126 using known etch mask formation processes. The mask 155 includes one or more openings therein, e.g., as formed by electron beam lithography on the photoresist material. Doped (e.g., n″) regions 124N, 126N are formed in the barrier and channel layers 124, 126, respectively, for example, by implanting dopants (e.g., n+ dopants) into the portions of the barrier layer 126 exposed by the mask 155, which may be followed by an activation anneal.

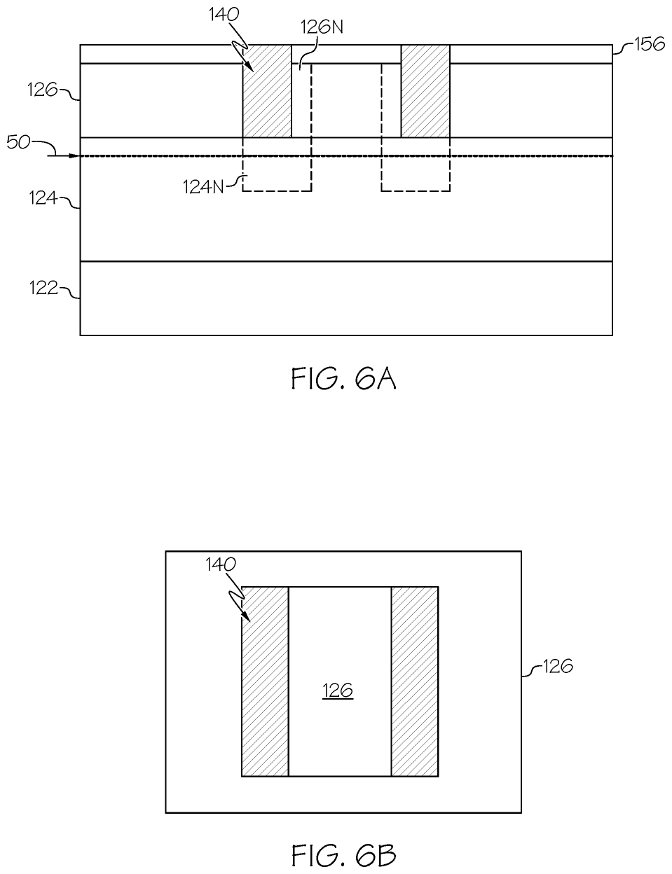

As shown in FIGS. 6A-6B, a mask 156 (e.g., a patterned photoresist mask) is formed on the barrier layer 126. The mask 156 includes one or more openings therein, which respectively expose the doped regions 126N. Respective recesses are formed through the barrier layer 126 (and any present passivation layers), for example, to expose the doped regions 124N of the channel layer 124. Ohmic contact elements 140 are formed (e.g., by a metal deposition and liftoff process) on the portions of layers 126, 124 exposed by the mask 156. For example, a conductive metal material may be deposited and annealed (e.g., at a temperature of about 600° C. to 1050° C.) to form the ohmic contact elements 140. The ohmic contact elements 140 may be in direct contact with the regions 126N and/or 124N.

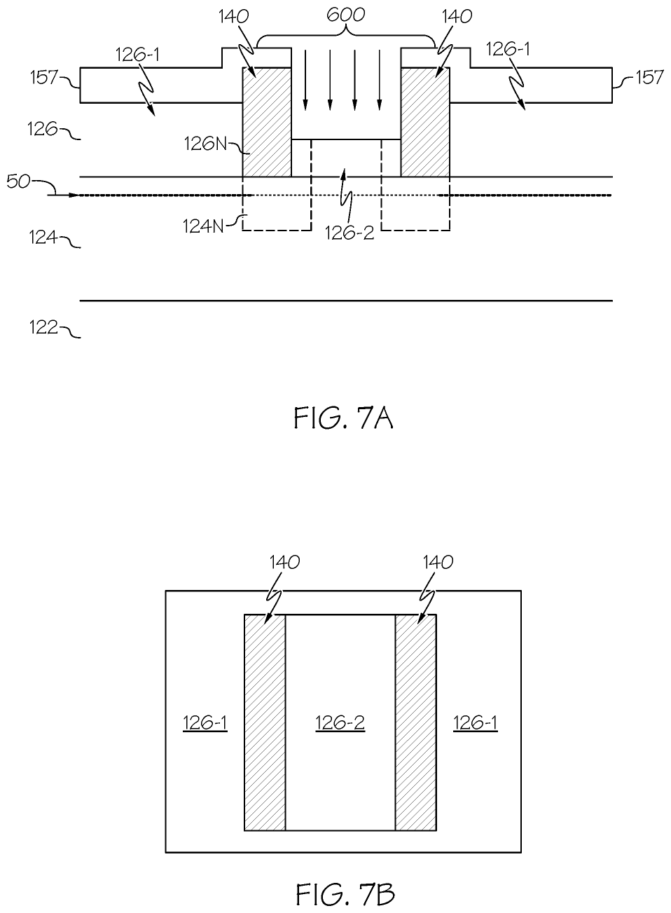

As shown in FIGS. 7A-7B, the method includes forming an etch mask 157 (e.g., a patterned photoresist mask) on the barrier layer 126 using known etch mask formation processes. The mask 157 includes an opening therein, e.g., as formed by electron beam lithography on the photoresist material. The opening in the etch mask 157 may have one or more desired lateral dimensions (e.g., between about 0.25 μm to about 1000 μm). The method further includes performing an atomic layer etching process 600 (such as a looped recess process 400, 400′ described herein) to etch the barrier layer 126 using the mask 157 to expose a surface of the barrier layer 126, thereby forming the recessed portion 126-2. The looped recess process 400, 400′ may remove, layer-by-layer, the barrier layer 126 in the inactive region to form the recessed portion 126-2. The recessed portion 126-2 may laterally extend (i.e., in the X-direction) between the ohmic contact elements 140, and may have one or more lateral dimensions between about 0.25 microns to about 1000 microns. The recessed portion 126-2 may include one or more of the characteristics (e.g., surface roughness, thickness T₂) described herein. In the example of FIGS. 7A-7B, the first portion of the barrier layer 126-1 is protected by the etch mask 157 during the looped plasma etch process 400, 400′. As described above, forming the recessed portion 126-2 locally reduces the carrier density (thereby locally increasing the sheet resistance) in portions of the barrier layer 126 exposed by the mask 157 (as indicated by the variations in the dashed line in FIG. 7A) to provide the integrated resistor 10 with a desired sheet resistance.

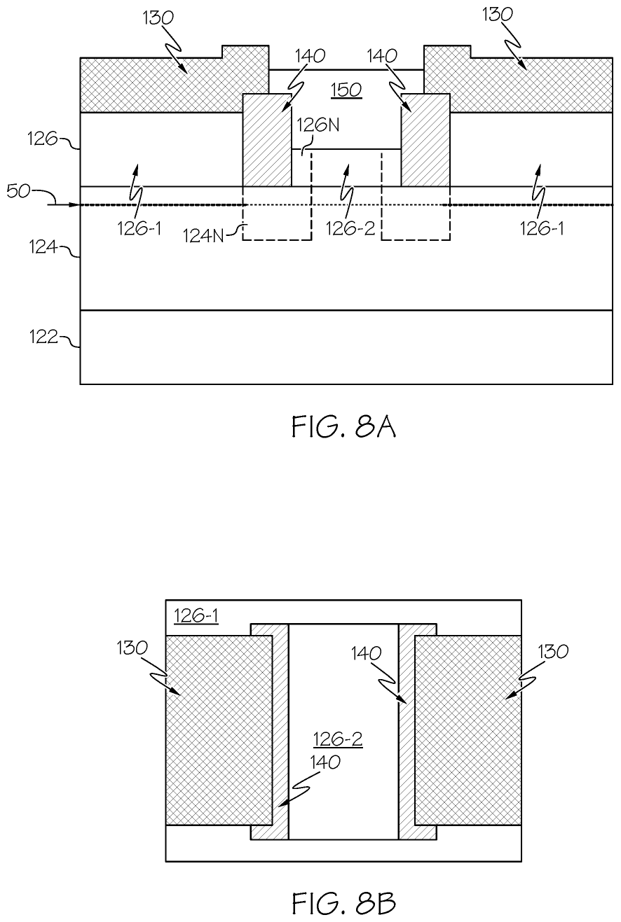

As shown in FIGS. 8A-8B, a surface passivation process is performed to form passivation layer 150 on the recessed portion 126-2 of the barrier layer 126. For example, a dielectric deposition process may be performed to cover at least the recessed portion 126-2. In transistor implementations, one or more front end processes may be performed to form gates, other passivation layers, field plates, etc. in the active region. A metallization process is performed to form contacts 130 on the semiconductor structure 190 in the inactive region such that the contacts 130 are electrically coupled to (and optionally, directly contact) the barrier layer 126 and the ohmic contact elements 140. For example, the contacts 130 may laterally extend from the ohmic contact elements 140 and onto portions 126-1 of the barrier layer on the non-conductive regions 128. Processes for depositing the contacts 130, may include, but are not limited to, sputtering, electroplating, or chemical vapor deposition. For example, a patterned photomask (including openings therein exposing the ohmic contact elements 140) may be formed on the semiconductor structure 190, and a metal deposition and liftoff process may be performed to form the contacts 130 on the ohmic contact elements 140. The conductive contacts 130, 140 at opposing ends of the portion 126-2 of the barrier layer 126 are electrically connected by the portion of the semiconductor structure 190 extending therebetween to define the integrated resistor 10.

In one variation of the method illustrated in FIGS. 5A-5B, 6A-6B, 7A-7B, and 8A-8B, the method includes forming the integrated resistor 11 of FIG. 1B as opposed to the integrated resistor 10 of FIG. 1A. That is, the passivation layer 150 may be formed directly on a portion of the barrier layer 126 and between the contacts 130 instead of forming the recessed portion 126-2. As a specific example, the barrier layer 126 and the channel layer 124 are provided on the substrate 122, and the doped regions 124N, 126N are formed in the barrier and channel layers 124, 126, respectively (as described above with reference to FIGS. 5A-5B). Subsequently, the ohmic contact elements 140, the passivation layer 150, and the contacts 130 are deposited onto the barrier layer 126 (as described above with reference to FIGS. 6A-6B and 8A-8B), thereby forming the integrated resistor 11 without performing the atomic layer etching process 600 (as described above with reference to FIGS. 7A-7B). More generally, embodiments of the present disclosure may include various combinations of the operations shown by way of example with reference to FIGS. 5A to 8B for forming the recessed portion 126-2 (of FIG. 1A) and/or the passivation layer 150 directly on the barrier layer 126 (of FIG. 1B) to provide devices including integrated resistors 10, 11 as described herein.

In some embodiments, before or after the contacts 130 are deposited onto the barrier layer 126, the method may include performing a surface preparation process on a portion 126-2′ of the barrier layer 126 to locally reduce the carrier density at the heterointerface between the channel layer 124 and the barrier layer 126 in the inactive region. Example surface preparation processes include, but are not limited to, wet cleaning processes and/or plasma processes (e.g., exposure to energetic species, such as remote nitrogen plasmas). Subsequently, the passivation layer 150 may be formed directly onto the portion 126-2 of the barrier layer 126 between the contacts 130 using one or more passivation formation processes, such as plasma-enhanced chemical vapor deposition (PECVD), thermal oxidation, atomic layer deposition, or spin coating. In some embodiments, the passivation layer formation process may include selectively modifying the component ratios of the passivation layer(s) 150 (e.g., silicon and nitride ratios for a SiN passivation layer 150) and/or a bulk dielectric charge density of the passivation layer 150 to thereby selectively locally control the carrier density and the sheet resistance of the integrated resistor 11.

Additional conductive connection elements may be formed on the contacts 130 to provide electrical connections to the integrated resistor 10, 11 whether implemented on the same substrate 122 as transistor structures (as shown in FIG. 2) or implemented as a standalone component (as shown in FIGS. 11A and 11B).

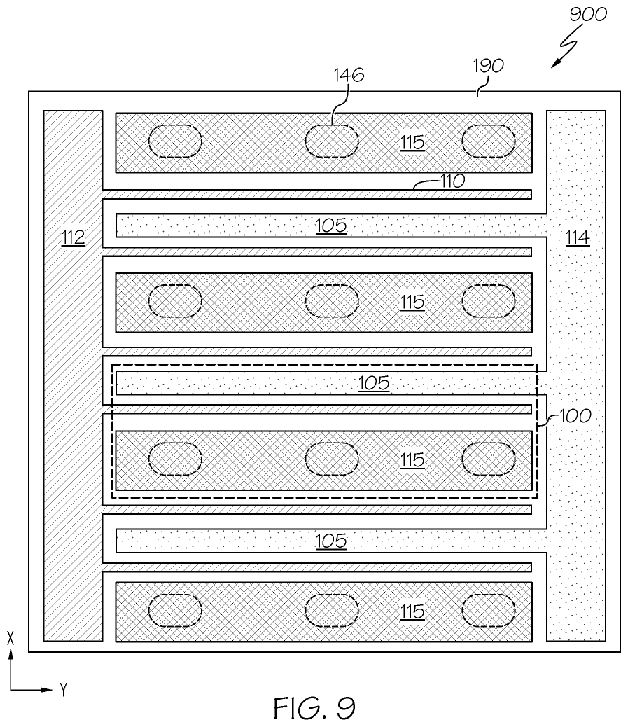

FIG. 9 is a schematic plan view of a Group III nitride-based transistor die according to embodiments of the present disclosure that illustrates metallization on a surface of the semiconductor structure thereof. As shown in FIG. 9, a transistor device or die 900 may include multiple transistor structures 200 connected in parallel to the contacts 130 of the integrated resistor 10 and/or the integrated resistor 11. For example, each of the gate 110, drain 105, and source 115 contacts may extend in a first direction (e.g., the Y-direction) to define gate, drain, and/or source ‘fingers’, which may be connected by one or more respective buses (e.g., by a gate bus and a drain bus on an upper surface of the semiconductor structure 190.

In FIG. 9, the gate fingers 110, drain fingers 105 and source fingers 115 may extend in parallel to each other, with the gate fingers 110 extending from the gate bus 112 in a first direction and the drain fingers 105 extending from the drain bus 114 in a direction opposite the first direction. Each gate finger 110 may be positioned between a drain finger 105 and a source finger 115 to define a unit cell 100. The gate fingers 110, drain fingers 105, and source fingers 315 (and connecting buses) may define part of gate-, drain-, and source-connected electrodes of the device, respectively, as defined by a top or frontside metallization structure. Dielectric layers that isolate the various conductive elements of the frontside metallization structure from each other are not shown in FIG. 9 to simplify the drawing. Since the gate fingers 110 are electrically connected to a common gate bus 112, the drain fingers 105 are electrically connected to a common drain bus 114, and the source fingers 115 are electrically connected together (e.g., through respective via openings 146), it can be seen that the unit cell transistors 100 are electrically connected together in parallel.

One of the terminals of the device (e.g., a source terminal connected to the source contact(s) 115) may be configured to be coupled to a reference signal such as, for example, an electrical ground. In some embodiments, a conductive through substrate via connection or structure (e.g., a backside via opening) may extend through the substrate 122 and epitaxial layer(s) 124, 126 to expose a portion of one of the contacts 105, 115, so as to allow for contact pads or terminals on the back side of the substrate (e.g., to couple the source contact 115 to ground). In other embodiments, a ground connection to one of the terminals device (e.g., the source terminal) may be provided outside the active area, e.g., in a peripheral area. In some embodiments, a backmetal layer on the back side of the substrate 122 may provide a backside ground plane, for example, in applications where proximity to ground may be desired.

While embodiments of the present disclosure have been described herein with reference to particular HEMT structures, the present disclosure should not be construed as limited to such structures, and may be applied to formation of many different transistor structures, such as pHEMTs (including GaAs/AlGaAs pHEMTs) and/or GaN MESFETs. Also, additional layers may be included in transistor structures while still benefiting from the teachings of the present disclosure. Such additional layers may include GaN cap layers, as described for example U.S. Pat. No. 6,548,333 to Smith. In some embodiments, insulating layers such as SiNx, or relatively high quality AlN may be deposited for making a MISHEMT and/or passivating the surface. The additional layers may also include a compositionally graded transition layer or layers. In addition, the barrier layer 126 and/or channel layer 124 described above may include multiple layers. Thus, embodiments of the present disclosure should not be construed as limiting these layers to a single layer but may include, for example, barrier layers having combinations of GaN, AlGaN and/or AlN layers.

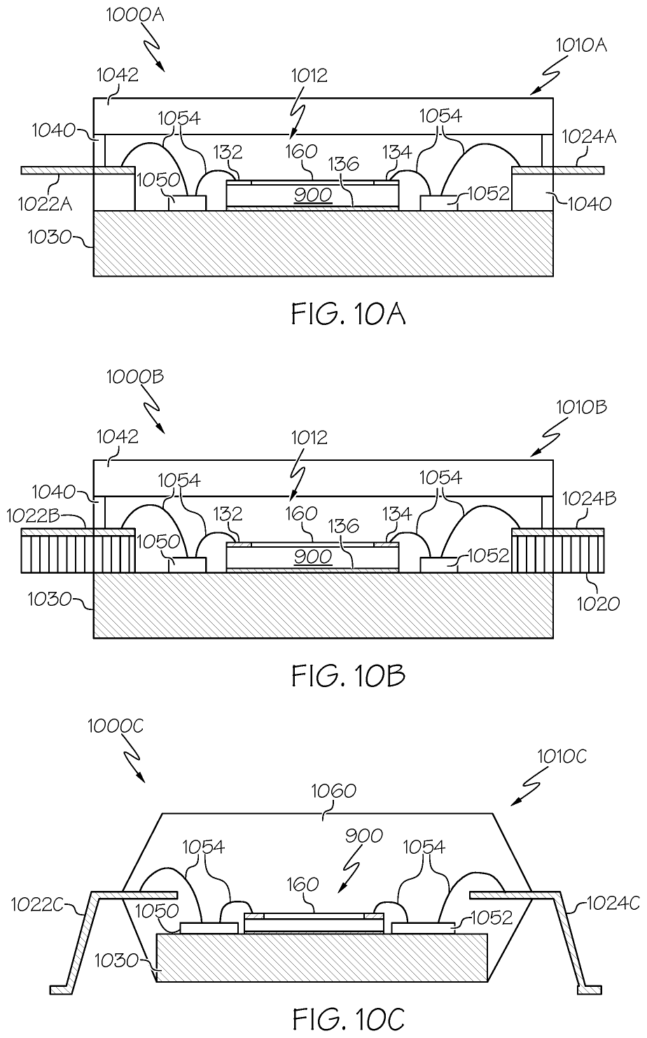

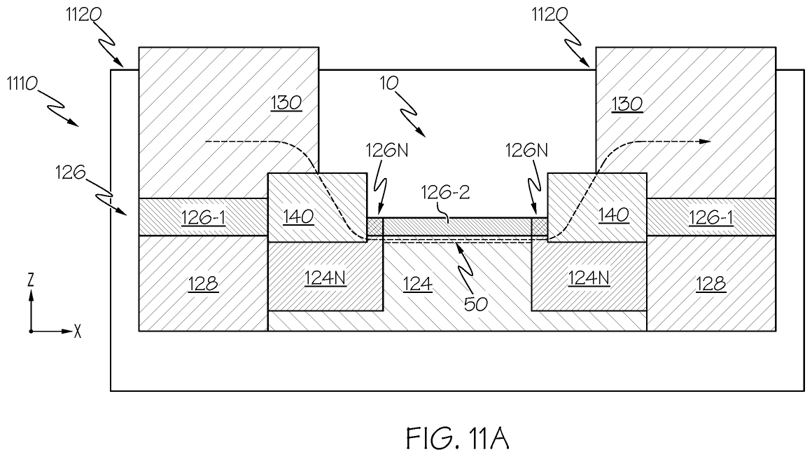

FIG. 10A is a schematic side view of a packaged Group III nitride-based RF transistor amplifier 1000A. As shown in FIG. 10A, packaged RF transistor amplifier 1000A includes the RF transistor amplifier die 900 packaged in an open cavity package structure 1010A. The package structure 1010A includes metal gate leads 1022A, metal drain leads 1024A, a metal submount 1030, sidewalls 1040 and a lid 1042.

The submount 1030 may include materials configured to assist with the thermal management of the package 1000A. For example, the submount 1030 may include copper and/or molybdenum. In some embodiments, the submount 1030 may be composed of multiple layers and/or contain vias/interconnects. In an example embodiment, the submount 1030 may be a multilayer copper/molybdenum/copper metal flange that comprises a core molybdenum layer with copper cladding layers on either major surface thereof. In some embodiments, the submount 1030 may include a metal heat sink that is part of a lead frame or metal slug. The sidewalls 1040 and/or lid 1042 may be formed of or include an insulating material in some embodiments. For example, the sidewalls 1040 and/or lid 1042 may be formed of or include ceramic materials. In some embodiments, the sidewalls 1040 and/or lid 1042 may be formed of, for example, Al₂O₃. The lid 1042 may be glued to the sidewalls 1040 using an epoxy glue. The sidewalls 1040 may be attached to the submount 1030 via, for example, brazing. The gate lead 1022A and the drain lead 1024A may be configured to extend through the sidewalls 1042, though embodiments of the present disclosure are not limited thereto.

The RF transistor amplifier die 900 is mounted on the upper surface of the metal submount 1030 in an air-filled cavity 1012 defined by the metal submount 1030, the ceramic sidewalls 1040 and the ceramic lid 1042. Gate and drain terminals 132, 134 of RF transistor amplifier die 900 are on the top side of the semiconductor structure 1100, while the source terminal 136 is on the bottom side of the semiconductor structure 1100. The source terminal 136 may be mounted on the metal submount 1030 using, for example, a conductive die attach material (not shown). The metal submount 1030 may provide the electrical connection to the source terminal 136 and may also serve as a heat dissipation structure that dissipates heat that is generated in the RF transistor amplifier die 900.

Input matching circuits 1050 and/or output matching circuits 1052 may also be mounted within the package 1000A. The matching circuits 1050, 252 may include impedance matching and/or harmonic termination circuits. The impedance matching circuits may be used to match the impedance of the fundamental component of RF signals that are input to or output from the RF transistor amplifier to the impedance at the input or output of the RF transistor amplifier die 900, respectively. The harmonic termination circuits may be used to ground harmonics of the fundamental RF signal that may be present at the input or output of the RF transistor amplifier die 900. More than one input matching circuit 1050 and/or output matching circuit 1052 may be provided. As schematically shown in FIG. 10A, the input and output matching circuits 1050, 1052 may be mounted on the metal submount 1030. The gate lead 1022A may be connected to the input matching circuit 1050 by one or more bond wires 1054, and the input matching circuit 1050 may be connected to the gate terminal 132 of RF transistor amplifier die 900 by one or more additional bond wires 1054. Similarly, the drain lead 1024A may be connected to the output matching circuit 1052 by one or more bond wires 1054, and the output matching circuit 1052 may be connected to the drain terminal 134 of RF transistor amplifier die 900 by one or more additional bond wires 1054. The bond wires 1054, which are inductive elements, may form part of the input and/or output matching circuits.

FIG. 10B is a schematic side view of a packaged Group III nitride-based RF transistor amplifier 1000B that includes the transistor device 100 packaged in a printed circuit board based package structure 1010B. The packaged RF transistor amplifier 1000B is very similar to the packaged RF transistor amplifier 1000A of FIG. 10A, except that the gate and drain leads 1022A, 1024A of package structure 1010A are replaced with printed circuit board based leads 1022B, 1024B in package structure 1010B.

The package structure 1010B includes a submount 1030, ceramic sidewalls 1040, a ceramic lid 1042, each of which may be substantially identical to the like numbered elements of package structure 1010A discussed above. The package structure 1010B further includes a printed circuit board 1020. Conductive traces on the printed circuit board 1020 form a metal gate lead 1022B and a metal drain lead 1024B. The printed circuit board 1020 may be attached to the submount 1030 via, for example, a conductive glue. The printed circuit board 1020 includes a central opening and the RF transistor amplifier die 900 is mounted within this opening on the submount 1030. Other components of RF transistor amplifier 1000B may be the same as the like-numbered components of RF transistor amplifier 1000A, and hence further description thereof will be omitted.

FIG. 10C is a schematic side view of another packaged Group III nitride-based RF transistor amplifier 1000C. RF transistor amplifier 1000C differs from RF transistor amplifier 1000A in that it includes a different package structure 1010C. The package structure 1010C includes a metal submount 1030 (which may be similar or identical to the submount 1030 of package structure 1010A), as well as metal gate and drain leads 1022C, 1024C. RF transistor amplifier 1000C also includes a plastic overmold 1060 that at least partially surrounds the RF transistor amplifier die 900, the leads 1022C, 1024C, and the metal submount 1030. Other components of RF transistor amplifier 1000C may be the same as the like-numbered components of RF transistor amplifier 1000A and hence further description thereof will be omitted.

The present disclosure is described with reference to the accompanying drawings, in which embodiments of the disclosure are shown. However, this disclosure should not be construed as limited to the embodiments set forth herein. Rather, these embodiments are provided so that this disclosure will be thorough and complete, and will fully convey the scope of the disclosure to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the disclosure herein is for the purpose of describing particular embodiments only and is not intended to be limiting of the disclosure. As used in the description of the disclosure and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the disclosure are described herein with reference to cross-section illustrations that are schematic illustrations of idealized embodiments (and intermediate structures) of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the disclosure.

Unless otherwise defined, all terms used in disclosing embodiments of the disclosure, including technical and scientific terms, have the same meaning as commonly understood by one of ordinary skill in the art to which this disclosure belongs, and are not necessarily limited to the specific definitions known at the time of the present disclosure being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entirety.

In the drawings and specification, there have been disclosed typical embodiments of the disclosure, and, although specific terms have been employed, they have been used in a generic and descriptive sense only and not for purposes of limitation.

1. A semiconductor device, comprising:
a semiconductor structure comprising first and second semiconductor layers having different bandgaps;
first and second contacts on the semiconductor structure and free of a gate structure therebetween; and
a resistor comprising a portion of the semiconductor structure that electrically connects the first and second contacts.

2. The semiconductor device of claim 1, wherein the portion of the semiconductor structure comprises a second portion of the second semiconductor layer that is recessed in thickness relative to a first portion thereof.

3. The semiconductor device of claim 2, wherein the first portion of the second semiconductor layer has a first electrical resistance associated therewith, and the second portion of the second semiconductor layer has a second electrical resistance associated therewith that is higher than the first electrical resistance.

4. The semiconductor device of claim 3, further comprising:
ohmic contact elements on the second portion of the second semiconductor layer and electrically coupling the first and second contacts to the second portion of the second semiconductor layer.

5. The semiconductor device of claim 1, further comprising:
a passivation layer on the portion of the semiconductor structure and in direct contact with the second semiconductor layer.

6. The semiconductor device of claim 1, wherein the portion of the first semiconductor layer extends between non-conductive regions of the semiconductor structure.

7. The semiconductor device of claim 6, wherein the first and second contacts extend onto the non-conductive regions of the semiconductor structure.

8. The semiconductor device of claim 2, wherein a thickness of the second portion is greater than about 2 nanometers (nm).

9. The semiconductor device of claim 8, wherein the second portion has one or more lateral dimensions of about 0.25 microns to about 1000 microns.

10. The semiconductor device of claim 2, wherein the first and second semiconductor layers comprise group III-nitride-based materials, wherein the second semiconductor layer comprises an aluminum composition of about 20 to about 35 percent, and the thickness of the second portion is about 5 nanometers (nm) to about 10 nm.

11. The semiconductor device of claim 1, further comprising:
source and drain contacts and a gate therebetween on an active region of the semiconductor structure, the active region comprising at least one transistor,
wherein the portion of the semiconductor structure continuously extends from the first contact to the second contact outside of the active region.

12. The semiconductor device of claim 11, wherein the resistor comprises a portion of an impedance matching, harmonic termination, or bias control circuit of the at least one transistor outside the active region.

13. The semiconductor device of claim 1, wherein the semiconductor device is a passive device and the semiconductor structure is free of transistors.

14. The semiconductor device of claim 1, wherein the resistor has a sheet resistance of about 300 ohm/square to about 2500 ohm/square.

15. A semiconductor device, comprising:
a semiconductor structure comprising a heterojunction between first and second semiconductor layers; and
an integrated resistor in the semiconductor structure, wherein the integrated resistor has a sheet resistance of about 300 ohm/square to about 2500 ohm/square.

16. The semiconductor device of claim 15, further comprising:
first and second contacts on the semiconductor structure and free of a gate structure therebetween,
wherein the integrated resistor comprises a portion of the semiconductor structure that electrically connects the first and second contacts.

17. The semiconductor device of claim 16, wherein the portion of the semiconductor structure comprises a second portion of the second semiconductor layer that is recessed in thickness relative to a first portion thereof.

18. The semiconductor device of claim 17, wherein the second portion of the second semiconductor layer extends between non-conductive regions of the semiconductor structure.

19. The semiconductor device of claim 18, wherein the first and second contacts extend onto the non-conductive regions of the semiconductor structure and are electrically coupled to the second portion of the second semiconductor layer.

20. The semiconductor device of claim 19, further comprising:
ohmic contact elements on the second portion of the second semiconductor layer and electrically coupling the second portion of the second semiconductor layer to the first and second contacts.

21. The semiconductor device of claim 17, wherein a thickness of the second portion is greater than about 2 nanometers (nm).

22. The semiconductor device of claim 16, further comprising:
a passivation layer on the portion of the semiconductor structure and in direct contact with the second semiconductor layer.

23. A semiconductor device, comprising:
a semiconductor structure comprising a heterojunction between a channel layer and a barrier layer thereon;
first and second contacts on the semiconductor structure and free of a gate structure therebetween; and
an integrated resistor comprising a second portion of the barrier layer that extends between the first and second contacts and is recessed in thickness relative to a first portion thereof.

24. The semiconductor device of claim 23, wherein the first portion of the barrier layer has a first electrical resistance associated therewith, and the second portion of the barrier layer has a second electrical resistance associated therewith that is higher than the first electrical resistance.

25. The semiconductor device of claim 23, wherein a thickness of the second portion is greater than about 2 nanometers (nm).

26. The semiconductor device of claim 25, wherein the second portion has one or more lateral dimensions of about 0.25 microns to about 1000 microns.

27. The semiconductor device of claim 23, wherein the channel layer and the barrier layer comprise group III-nitride-based materials, wherein the barrier layer comprises an aluminum composition of about 20 to about 35 percent, and the thickness of the second portion is about 5 nanometers (nm) to about 10 nm.

28. A semiconductor device, comprising:
a semiconductor structure comprising a heterojunction between a channel layer and a barrier layer thereon;
first and second contacts on the semiconductor structure and free of a gate structure therebetween;
a passivation layer directly on a portion of the barrier layer between the first and second contacts; and
an integrated resistor that electrically connects the first and second contacts and comprises the portion of the barrier layer having the passivation layer thereon.

29. The semiconductor device of claim 28, wherein the portion of the barrier layer is a second portion thereof, and the second portion of the barrier layer has a higher electrical resistance associated therewith than that of first portions thereof adjacent the first and second contacts.

30. The semiconductor device of claim 28, wherein the channel layer and the barrier layer comprise group III-nitride-based materials, wherein the barrier layer comprises an aluminum composition of about 20 to about 35 percent, and the passivation layer comprises silicon nitride.

31. A method of fabricating a semiconductor device, the method comprising:
providing a semiconductor structure comprising first and second semiconductor layers having different bandgaps;
performing a looped recess process to recess a thickness of a second portion of the second semiconductor layer relative to a first portion thereof; and
forming first and second contacts on the semiconductor structure,
wherein the second portion of the second semiconductor layer comprises an integrated resistor that electrically connects the first and second contacts.

32.-39. (canceled)

40. A method of fabricating a semiconductor device, the method comprising:
providing a semiconductor structure comprising first and second semiconductor layers having a heterojunction therebetween;
forming a passivation layer directly on a portion of the second semiconductor layer; and
forming first and second contacts on the semiconductor structure,
wherein the portion of the second semiconductor layer having passivation layer thereon comprises an integrated resistor that electrically connects the first and second contacts free of a gate electrode therebetween.

41.-43. (canceled)
